(19) United States
(12) Patent Application Publication
(10) Pub. No.: US 2006/0107898 A1
(43) Pub. Date: May 25, 2006

(54) Method and apparatus for measuring consumption of reactants

(76) Inventor: Tom E. Blomberg, Vantaa (FI)

Correspondence Address: KNOBBE MARTENS OLSON & BEAR LLP, 2040 MAIN STREET, FOURTEENTH FLOOR, IRVINE, CA, 92614, US

(21) Appl. No.: 10/993,088

(22) Filed: Nov. 19, 2004

(51) Int. Cl. C23C 16/00; B05C 11/00; G01N 7/00

(52) U.S. Cl. 118/715; 427/248.1; 118/712; 73/31.04

(57) ABSTRACT

A method and apparatus for measuring the consumption of reactants includes a partial pressure sensor for measuring the partial pressure of a reactant in a reactant stream. The partial pressure sensor includes a first pressure sensor that has a first sensitivity to the composition of the gas stream and a second pressure sensor that has a second sensitivity to the composition of the reactant stream, the second sensitivity being greater than the first sensitivity. A control unit is configured to compare a first pressure signal from the first pressure sensor to a second pressure signal from the second pressure sensor to determine the partial pressure of the reactant in the reactant stream.

### BACKGROUND OF THE INVENTION

1. Field of the Invention

The present invention relates to chemical processes in which a processing chemical is supplied to a reactor. More particularly, the invention relates to measuring the consumption of the chemical reactants supplied to the reactor.

2. Description of the Related Art

There are several vapor deposition methods for growing thin films on the surface of substrates. These methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Epitaxy (ALE), which is more recently referred to as Atomic Layer Deposition (ALD).

ALE or ALD is a deposition method that is based on the sequential introduction of precursor species (e.g., a first precursor and a second precursor) to a substrate, which is located within a reaction chamber. The growth mechanism relies on the adsorption of one precursor on active sites of the substrate. Conditions are typically arranged such that no more than a monolayer forms in one pulse so that the process is self-terminating or saturative. For example, the first precursor can include ligands that remain on the adsorbed species, which prevents further adsorption. Temperatures are maintained above precursor condensation temperatures and below thermal decomposition temperatures such that the precursor chemisorbs on the substrate(s) largely intact. This step of adsorption is typically followed by a first evacuation or purging stage wherein the excess first precursor and possible reaction byproducts are removed from the reaction chamber. The second precursor is then introduced into the reaction chamber. The second precursor typically reacts with the adsorbed species, thereby producing the desired thin film. This growth terminates once the entire amount of the adsorbed first precursor has been consumed. The excess of second precursor and possible reaction byproducts are then removed by a second evacuation or purge stage. The cycle can be repeated so as to grow the film to a desired thickness. Cycles can also be more complex. For example, the cycles can include three or more reactant pulses separated by purge and/or evacuation steps.

ALE and ALD methods are described, for example, in Finnish patent publications 52,359 and 57,975 and in U.S. Pat. Nos. 4,058,430 and 4,389,973, which are herein incorporated by reference. Apparatuses suited to implement these methods are disclosed in, for example, U.S. Pat. No. 5,855,680, Finnish Patent No. 100,409, Material Science Report 4(7) (1989), p. 261, and Tyhjiotekniikka (Finnish publication for vacuum techniques), ISBN 951-794-422-5, pp. 253-261, which are incorporated herein by reference. ASM Microchemistry Oy, Espoo, Finland, supplies equipment suitable for the ALD process under the trade name ALCVD™.

According to conventional techniques, such as those disclosed in FI Patent publication 57,975, the purging stages involve a protective gas pulse, which forms a diffusion barrier between precursor pulses and also sweeps away the excess precursors and the gaseous reaction products from the substrate. Valves typically control the pulsing of the precursors and the purge gas. The purge gas is typically an inert gas, for example, nitrogen.

In some ALD reactors, some or all of the precursors may be initially stored in a container in a liquid or solid state. Such reactors are disclosed in U.S. Pat. No. 6,699,524, issued Mar. 2, 2004 and U.S. Pat. No. 6,783,590, issued Aug. 31, 2004, which are hereby incorporated herein by reference. Within the container, the precursor is heated to convert the solid or liquid precursor to a gaseous or vapor state. Typically, a carrier gas is used to transport the vaporized precursor to the reactor. The carrier gas is usually an inert gas (e.g., nitrogen), which can be the same gas that is used for the purging stages.

One problem associated with such ALD reactors and other chemical processes that use solid or liquid precursors is that it is difficult to determine how much solid or liquid precursor is left in the container. For example, low pressure is often required to volatilize the solid or liquid and the precursor may be highly flammable, explosive, corrosive and/or toxic. As such, the container is usually isolated from the surroundings except for the gas inlet and outlet conduits during use. Conventional measuring devices positioned in the container can be damaged and/or are impractical. As such, the chemical process is typically allowed to continue until the supply of precursor is exhausted. Operating in this manner is generally undesirable because it allows the concentration of the precursor in the reactor to drop below an ideal concentration range when the source is about to become depleted. One solution is to calculate the rate of precursor removal. Based upon the calculation, the container can be changed before the precursor is expected to be exhausted. However, a safety margin is typically included in the calculation. This can result in unused precursor remaining in the container, such that refilling is performed prematurely and the reactor downtime is increased (i.e., the duration of reactor use between refilling is reduced).

Another method for determining how much solid or liquid precursor is left in a container is disclosed in U.S. Pat. No. 6,038,919. This method involves closing an outlet of the container to define a measurement volume. A metered amount of gas is delivered to the measurement volume, while the pressure in the measurement volume is monitored. The pressure is used to calculate the amount of precursor remaining in the container. This method also has disadvantages. For example, the outlet of the container is closed, which increases the downtime of the reactor.

### SUMMARY OF THE INVENTION

Accordingly, one embodiment of the present invention comprises a method for a partial pressure sensor apparatus for determining the partial pressure of a first component in a gas stream having a composition comprising at least the first component and one other component. The apparatus comprises a first pressure sensor that has a first sensitivity to the composition of the gas stream and a second pressure sensor that has a second sensitivity to the composition of the gas stream. The second sensitivity is greater than the first sensitivity. A control unit is configured to compare a first pressure signal from the first pressure sensor to a second pressure signal from the second pressure sensor to determine the partial pressure of the first component in the gas stream.

Another embodiment of the present invention comprises a method for determining the partial pressure of a first component in a gas stream having a composition comprising at least the first component and one other component. In the method, the pressure of the gas stream is measured using a first pressure sensor that has a first sensitivity to the composition of the gas stream. The pressure of the gas stream is also measured using a second pressure sensor that has a second sensitivity to the composition of the reactant stream, the said second sensitivity being greater than the first sensitivity. A first pressure signal from the first pressure sensor is compared to a second pressure signal from the second pressure sensor to determine the partial pressure of the first component in the gas stream.

Another embodiment of the present invention comprise a method for determining the changes in a reactant supply system that is designed to supply repeated pulses of a vapor phase reactant to a reaction chamber of an ALD system. The method comprises providing a purging gas source, providing a reactant source that comprises a solid or liquid reactant and a vaporizing mechanism for producing a first reactant and providing a conduit system to connect the reactant source to the reaction chamber and to connect the purging gas source to the reaction chamber. At least one valve is positioned in the conduit system such that switching of the valve induces alternating vapor phase reactant pulses from the reactant source to the reaction chamber and purging pulses from the purging gas source to the reaction chamber. The valve is repeatedly switched to induce repeated alternating vapor phase reactant and purging pulses. The pressure in the conduit system is determined with a first pressure sensor that has a first sensitivity to the composition of the gas stream and with a second pressure sensor that has a second sensitivity to the composition of the reactant stream. The second sensitivity is greater than the first sensitivity. The first signal is compared to the second signal.

Another embodiment of the present invention comprises an apparatus for supplying repeated vapor phase reactant pulses to a reaction chamber. The apparatus includes a reactant source for a first reactant, a gas conduit system that connects the reactant source and the reaction chamber and a valve positioned in the gas conduit system such that switching of the valve induces vapor phase reactant pulses from the reactant source to the reaction chamber. The apparatus also includes a first pressure sensor that has a first sensitivity to the composition of the gas stream and a second pressure sensor that has a second sensitivity to the composition of the reactant stream, the second sensitivity being greater than the first sensitivity. A control unit is configured to compare a first pressure signal from the first pressure sensor to a second pressure sensor from the second pressure signal.

Another embodiment of the present invention comprises a semiconductor processing tool. The tool comprises a reactant source comprising a solid or liquid phase reactant, a rector and a conduit system for placing the reactant source in communication with the reactor. A first pressure sensor is provided measuring the pressure in the conduit system. A second pressure sensor is also provided for measuring the pressure in the conduit system. A monitoring apparatus is configured to compare the measurements of the first pressure sensor and the second pressure sensor and relate the comparison to an amount of solid or liquid phase reactant left in the reactant source.

It should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

It should also be noted that all of these embodiments are intended to be within the scope of the invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

In the following, the invention will be described in greater detail with the help of exemplifying embodiments illustrated in the appended drawings, in which like reference numbers are employed for similar features in different embodiments and, in which

FIG. 1 is a schematic illustration of an apparatus for supplying a reactant to a reaction chamber according to a first embodiment of the present invention.

FIG. 2 is a pressure-time graph showing the pressure as measured by a first pressure sensor and a second pressure sensor.

FIG. 3 is a schematic illustration of an apparatus for supplying repeated vapor phase reactant pulses to a reaction chamber according to an embodiment of the present invention.

### DETAILED DESCRIPTION OF THE PREFERRED EMBODIMENTS

Embodiments of a method and apparatus for determining the partial pressure of a substance in a two or more substance environment will now be described. As will be explained below, these embodiments may be used to determine the amount of liquid or solid reactant in a reactant source container.

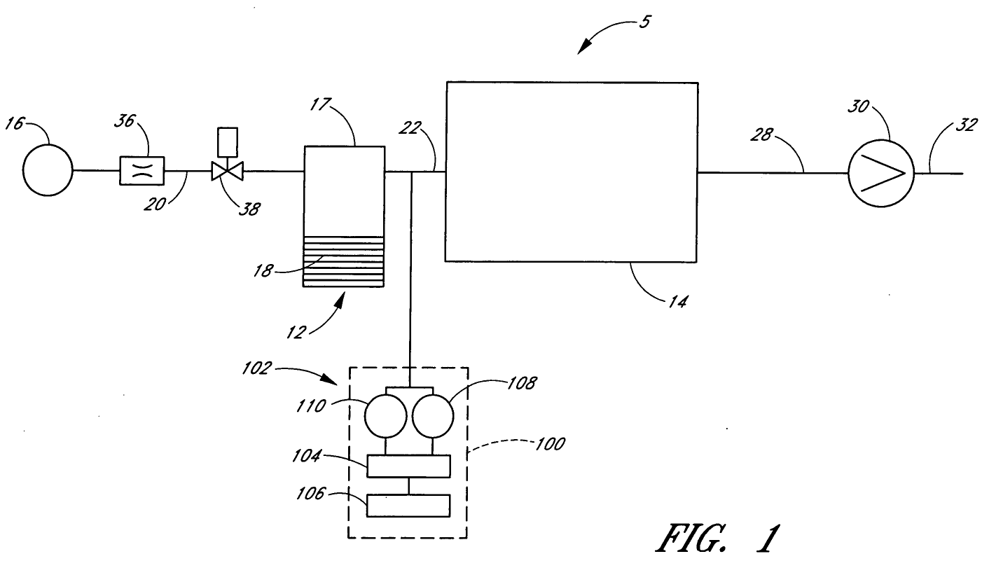

FIG. 1 is a schematic illustration of an exemplary reactor system 5, which is configured to supply a vapor phase reactant to a reaction chamber 14. The reactor system 5 utilizes a liquid or solid reactant source container 12, which employs a carrier gas to transport vapor of a reactant material 18 from the reactant source container 12 to the reaction chamber 14. As such, the exemplary reaction system 5 represents one particular environment in which it is advantageous to determine the amount of liquid or solid reactant material 18 in the reactant source container 12. However, it should be appreciated that the methods and apparatuses described below may also have utility in reactor systems that utilize, for example, a reactant that is gaseous under standard conditions.

As shown in FIG. 1, the exemplary reactor system 5 comprises an inactive or carrier gas source 16, the reactant source container 12 and the reaction chamber 14. The inactive gas source 16 provides an inactive gas to facilitate transport of the vapor of the reactant material 18 to the reaction chamber 14. Examples of inactive gases include, but are not limited to, nitrogen gas and noble gases (e.g., argon).

The illustrated reactant source container 12 includes an enclosure or vessel 17, which is capable of containing the solid and/or liquid reactant material 18 and in which the reactant material 18 can be vaporized. It is generally provided with an inlet nozzle (not shown), which is connected to a carrier gas supply conduit 20 for introduction of a carrier gas into the container 12 from the inactive gas source 16. The container 12 is also provided with an outlet nozzle (not shown), which is connected to the inlet conduit 22, which interconnects the reactant source container 12 with the reaction chamber 14 through an inlet conduit 22. The reactant source container 12 can be equipped with a heater (not shown) for vaporizing the reactant material 18. Alternatively, the reactant material 18 may be heated by feeding heated carrier gas into the reactant source container 12. One embodiment of a reactant source container is described in co-pending U.S. patent application Ser. No. 09/854,706, filed May 14, 2001, the entire contents of which are hereby incorporated by reference herein. In another embodiment, the reactant source container 12 may be positioned within an enclosure that may be evacuated and provided with radiant heaters to heat the source container 12. See e.g., U.S. Pat. No. 6,699,524, issued Mar. 2, 2004, and U.S. Pat. No. 6,783,590, issued August 31, 2004, which are hereby incorporated herein by reference.

An outlet conduit 28 is connected to the reaction chamber 14 for removing unreacted vapor-phase reactants and reaction by-products from the reaction chamber 14. The outlet conduit 28 is preferably connected to a vacuum source (e.g., an evacuation pump) 30. An exhaust conduit 32 is, in turn, connected to the outlet of the evacuation pump 30.

With continued reference to FIG. 1, a mass flow controller 36 and a pulsing valve 38 are positioned along the carrier gas supply conduit 20 for controlling the flow of inactive gas into the reactant source container 12.

As mentioned above, one problem associated with systems that use vaporized liquid and/or solid reactants is that it is difficult to determine how much solid and/or liquid reactant is left in the reactant source container 12. The solid or liquid reactant may be highly flammable, explosive, corrosive and/or toxic. As such, the reactant source container 12 is typically sealed during use. Conventional measuring devices positioned in the reactant container can be damaged and/or are impractical. As such, the chemical process is typically allowed to continue until the supply of liquid or solid reactant in the reactant container is exhausted. Operating in this manner is generally undesirable because it allows the concentration of the reactant in the reactor 14 to drop below an ideal concentration range when the source is about to become depleted of the reactant. This is particularly problematic for semiconductor processing, since dosage cannot accurately be measured in the vapor pressure changes excessively due to chances in concentration. One solution is to calculate the rate of reactant removal from the reactant source container 12. Based upon the calculation, the reactant source container 12 can be changed before the reactant is exhausted. However, a safety margin is typically included in the calculation. This can result in unused precursor remaining in the container.

Accordingly, the illustrated system 5 includes a monitoring apparatus 100, which is preferably operatively connected to the inlet conduit 22 extending between the reactant source container 12 and the reaction chamber 14. In the illustrate embodiment, the monitoring apparatus includes a partial pressure sensor 102, a control unit 104 and an alarm or display 106.

The control unit 104 is operatively connected to the partial pressure sensor 102. The control unit 104 generally comprises a general purpose computer or workstation having a general purpose processor and memory for storing a computer program that can be configured for performing the steps and functions described below. In the alternative, the unit can comprise a hard wired feed back control circuit, a dedicated processor or any other control device that can be constructed for performing the steps and functions described below. The control unit 104 is preferably is operatively connected to the alarm and/or display device 106, which can comprise a display unit for displaying information gathered by the control unit 104.

In illustrated embodiment, the partial pressure sensor 102 comprises a first pressure sensor 108 and a second pressure sensor 110. The first and second pressure sensors 108, 110 preferably have different sensitivities to the composition of the gas in the inlet conduit 22. More preferably, the first sensor 108 is substantially insensitive to the composition of the gas in the conduit 22 while the second sensor 110 is sensitive to the composition of the gas in the conduit. As will be explained in detail below, the monitoring apparatus 100 may utilize these different sensitivities to determine the consumption of reactant 18 in the reactant source container 12.

As mentioned above, the first pressure sensor 108 is preferably substantially insensitive to the composition of the gas in the conduit 22. For example, in one preferred embodiment, the first sensor comprises a mechanical pressure sensor, such as, for example, a capacitive pressure sensor or a piezoelectric pressure sensor. Such mechanical pressure sensors are well know to those of skill in the art and are generally insensitive to the composition of the gas being measured. Mechanical sensors are generally based on material changes caused by stress placed on a membrane or other flexible element within the sensor. For example, a piezoelectric pressure sensor typically includes a piezoelectric material (e.g., a quartz crystal), which generates a voltage when pressure is applied to the material. The voltage varies as a function of pressure and therefore the voltage or current derived from the voltage may be used by the control unit 104 to determine pressure. In a similar manner, a capacitive pressure sensor typically includes a pair of plates that moves towards or away from each other as the pressure changes. In this manner, the capacitance between the plates changes as a function of pressure. Of course those of skill in the art will recognize that any of a variety of other pressure sensors and/or mechanical pressure sensors may be used in light of the goal of providing a first pressure sensor 108 that has a different sensitivity to gas composition as compared to the second pressure sensor 110 and, more preferably is substantially insensitive to gas composition.

As mentioned above, the second sensor 110 preferably has a different sensitivity to gas composition as compared to the first sensor 108 and, more preferably, is more sensitive to gas composition as compared to the first sensor 108. Any of a variety of known sensors may be used, such as, for example, thermocouples, Pirani sensors, or convection gauges. A pressure sensor that uses a thermocouple typically involves supplying an electrical current to heat a portion of a device positioned within the gas to be measured. The temperature of the heated portion of the device is measured by monitoring fluctuations in the electrical voltage of a thermocouple element configured to measure the temperature of the heated portion. As the pressure falls, the rate of cooling of the heated portion by the ambient gas decreases. As a result, either the temperature of the heated portion rises or the electrical current needed to keep the heated portion at constant temperature decreases.

A Pirani gauge is similar to pressure sensors that use thermocouples except that the heating element and temperature element are typically combined into a single wire. In a Pirani gauge, the wire is generally heated and the resistance of the wire is monitored. As the pressure decreases, less heat is transferred from the wire to the surrounding gas. This results in an increased filament temperature which increases the resistivity of the wire.

A convection gauge is similar to the Pirani gauge, but measures the resistivity of a wire (e.g., a gold-plated tungsten wire) to detect the cooling effects of both conduction and convection, and thereby extends the sensing range as compared to the Pirani gauge. At higher vacuums, response depends on the thermal conductivity of the gas within which the wire is positioned, while at lower vacuums it depends on convective cooling by the gas molecules. The resistivity of the filament changes when the temperature of the filament changes. The thermal capacity of the filament depends on the pressure and thermal conductivity (or thermal capacity) of the surrounding gas atmosphere.

It should be appreciated, therefore, that thermocouples, Pirani sensors, and convection gages are all generally sensitive to the composition of the gas being measured. Specifically, the cooling of the filament is a function of the thermal properties of the gas (e.g., heat capacity, conduction, etc.). Such sensors are therefore typically calibrated for a particular gas composition. Deviations from the calibrated gas composition will result in a deviation from the calibrated pressure curve.

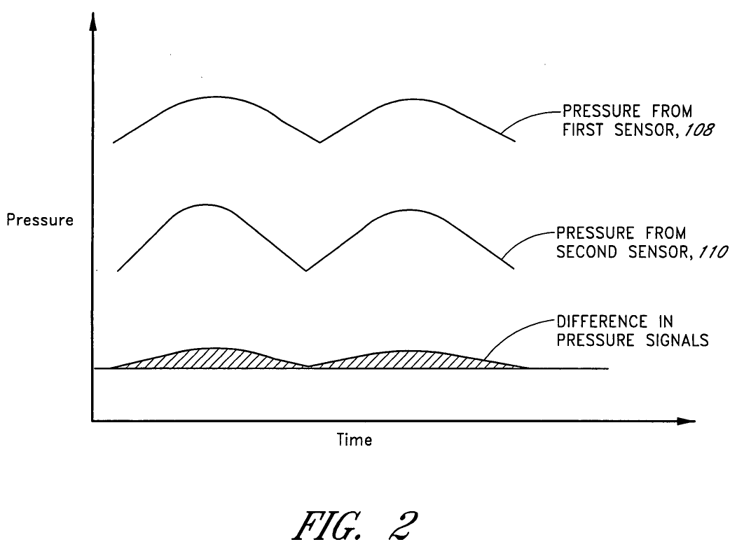

With reference to FIG. 2, a method for using the signals from the two pressure sensors 108, 110 to determine the partial pressure of the gas in the inlet conduit 22 will now be described. As shown in FIG. 2, the pressure from the two pressure sensors vary as a function of time as the reactant is supplied to the reaction chamber 14. As mentioned above, the pressure for the first sensor 108 is generally insensitive to the composition of the gas being measured and therefore generally fluctuates in response to the flow of the carrier gas into the reaction chamber 14 and/or valves and pumping strength downstream of the reactant source container 12. In contrast, the pressure of the second sensor 110 is sensitive to the composition of the gas. As the amount of the reactant material 18 in the reactant source container 12 decreases, the composition of the inactive gas - reactant vapor mixture in the inlet conduit 22 changes over time. This causes the signal from the second pressure sensor 110 to also change over time as compared to the signal of the first pressure sensor 108.

The difference between the signals from the first and second pressure sensors 108, 110 is generally proportional to the partial pressure of the vapor of the reactant material 18 in the inlet conduit 22. In one embodiment a lookup table containing reference data about gas mixtures may be stored within the control unit 104 such that a certain difference signal value between the two signals corresponds to a certain partial pressure of the reactant. The lookup table can be compiled from calibration measurements. For example, the source chemical may be heated to a specified temperature and the vapor and solid phases of the source are allowed to reach an equilibrium state. The equilibrium vapor pressure of the reactant at the specified temperature can often be found from the scientific literature (e.g., CRC Handbook of Chemistry and Physics, 61^{st} edition, CRC Press, Inc., Fla., 1980, pp. D-199-D-221). The difference signal is measured and the value is tagged together with the known value of the absolute vapor pressure. The number pair is then stored in the lookup table. In another embodiment, the difference signal value and the temperature value of the measured gas are placed to an equation derived from experiments for calculating the partial pressure of the reactant vapor. In these manners, the partial pressure or an equivalent reading of the gas phase reactant in the inlet conduit 22 may be determined.

The partial pressure or an equivalent reading may be used in several different methods for determining the consumption of the reactant 18 in the container 12. For example, in one embodiment, the control unit 104 may be configured to detect a sudden or significant decrease in the partial pressure of the reactant as measured by a threshold differential per unit time, and thereby send a signal through the display unit 106 indicating that the container 12 needs to be replaced.

In another embodiment, the control unit 104 may be configured to integrate the partial pressure or equivalent reading of the reactant over time. In this manner, the control unit may calculate the chemical consumption of the reactant 18 in the source container 12.

According to still another embodiment a reference source container may be filled with the reactant and weighed. The reference container may then be heated to the normal source temperature and a predetermined amount of reactant is removed from the container. For example, in one embodiment, 1000 pulses of the reactant vapor is removed with the help of inactive carrier gas. During the pulses, a partial pressure transducer 102 measures and integrates the partial pressure over time. After the pulses are complete, the reference container is weighed again to determine the amount of reactant consumed. The integrated value may then be correlated to the weight loss of the reference container. This process may be repeated for more and/or less pulses. These values may then be used to extrapolate to, for example, an integrated value that corresponds to 80% weight loss of the reactant in the reference container. The control unit 104 may be provided with this value such that by monitoring the partial pressure signal during a chemical process the control unit 104 accurately predicts when it is time to schedule a replacement of the reactant container 12 before the container 12 becomes depleted of the reactant.

It should be appreciated that in the embodiments described above the partial pressure needs not to be determined. That is to say, equivalent readings or values may be used. For example, in one embodiment, the monitoring apparatus 100 may be configured to utilize the signal difference between the first and second sensors 108, 110 without converting the difference to a partial pressure value.

The above-described embodiments have several advantages. For example, by providing a signal that is proportional to the partial pressure of the reactant in the inlet conduit 22, the monitoring apparatus 100 may be used to determine how much reactant 18 in the source container 12 has been consumed. In one embodiment, this may be determined by simply observing the decrease in the partial pressure of the reactant over time. In another embodiment, the difference between the signals from the first and second pressure sensors may be integrated over time to determine the amount of reactant consumed. In this manner, the source container 12 may be changed before it becomes completely exhausted.

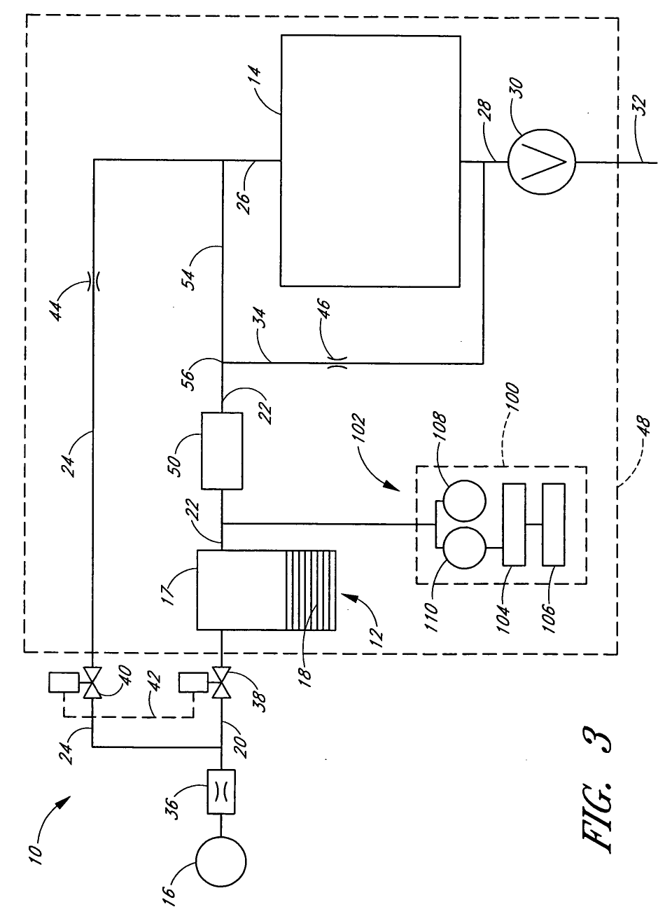

FIG. 3 is a schematic illustration of an exemplary Atomic Layer Deposition (“ALD”) system 10, which represents one particular environment in which it is particularly advantageous to determine the amount of liquid or solid reactant in the reactant source container 12. In the following description of the ALD system 10, the same reference numbers will be used to describe components described above.

The ALD system 10 is configured for supplying repeated vapor phase reactant pulses to a substrate (not shown). The ALD system 10 also utilizes the liquid or solid reactant source container 12, which employs a carrier gas to transport the reactant vapor from the reactant source container 12 to a reaction chamber 14. The exemplary ALD system 10 also comprises an inactive gas source 16, the reactant source container 12 and the reaction chamber 14 in which one or more substrates (not shown) can be positioned. In a more typical ALD system, at least two sources of two mutually reactive reactants are provided and the substrate is subjected to alternating and repeated pulses of both reactants. However, for the purpose of illustrating the present embodiment, only one reactant source is indicated. The inactive gas source 16 provides an inactive gas to facilitate transport of the reactant to the reaction chamber 14 and to purge the reaction chamber 14. In the present context, “inactive gas” refers to a gas that is admitted into the reaction chamber 14 and which does not react with a reactant or with the substrate. Examples of suitable inactive gases include, but are not limited to, nitrogen gas and noble gases (e.g., argon). As is well known in the art of ALD processing, purging of the reaction chamber 14 involves feeding an inactive gas into the reaction chamber 14 between two sequential and alternating vapor-phase pulses of the reactants from the reactant source container 12 and a second reactant source, not shown. The purging is carried out in order to reduce the concentration of the residues of the previous vapor-phase pulse before the next pulse of the other reactant is introduced into the reaction chamber 14. In other arrangements, the chamber can be simply pumped down between reactant pulses.

In the illustrated arrangement, the same inactive gas, from a single source, is used as carrier gas and as purge gas. In alternative embodiments two separate sources can be used, one for carrier gas and one for purge gas. As will be explained below, the purging gas can also be used for providing a gas barrier against the flow of residual reactant into the reaction chamber 14 during the purging of the reaction chamber 14.

As described above, the reactant source container 12 includes an enclosure or a vessel 17, which is capable of containing the solid and/or liquid reactant material 18. It is generally provided with an inlet nozzle (not shown), which is connected to a carrier gas supply conduit 20 for introduction of a carrier gas into the reactant source container 12 from the inactive gas source 16. The container 12 is also provided with an outlet nozzle (not shown), which is connected to the reactant conduit 22, which interconnects the reactant source container 12 with the reaction chamber 14 through an inlet conduit 26. As explained above, the reactant source container 12 can be equipped with a heater for vaporizing the reactant material 18. Alternatively, heated carrier gas may be fed to the reactant source container 12 or the container 12 may be placed within a heated enclosure.

In the exemplary embodiment, the inactive gas source 16 is also connected to the reaction chamber 14 through a purge conduit 24, which is connected to the inlet conduit 26 of the reaction chamber 14.

An outlet conduit 28 is connected to the reaction chamber 14 for removing unreacted vapor-phase reactants and reaction by-products from the reaction chamber 14. The outlet conduit 28 is preferably connected to the evacuation pump 30. An exhaust conduit 32 is, in turn, connected to the outlet of the evacuation pump 30.

The exemplary ALD system 10 also preferably includes a bypass conduit 34. The bypass conduit 34 includes a first end connected to the reactant conduit 22 at a point between the reactant gas source 12 container and the inlet conduit 26 of the reaction chamber 14. A second end of the bypass conduit 34 is connected to the outlet conduit 28. In a modified arrangement, the bypass conduit 34 can be connected directly to the evacuation pump 30 or to a separate evacuation pump.

In the illustrated arrangement, the conduits described above are preferably formed from inert material, such as, for example, an inert metal, ceramic material or glass.

With continued reference to FIG. 3, the mass flow controller 36 and the pulsing valve 38 are positioned along the carrier gas supply conduit 20. The purging conduit 24 preferably also includes a shut-off valve 40, which in this embodiment will be referred to as the purging valve 40. As will be explained below, the pulsing valve 38 and the purging valve 40 can be used to alternately direct the carrier gas to the reactant source container 12 and to the purging conduit 24. For this purpose, the pulsing valve 38 and the purging valve 40 are preferably connected by a connection 42, such that the valves 38 and 40 are oppositely switched simultaneously. Consequently, when the pulsing valve 38 is opened, the purging valve 40 is closed, and when the pulsing valve 38 is closed, the purging valve 40 is opened. The connection 42 can be operated mechanically, pneumatically or via a control loop.

Preferably, flow restrictors 44 and 46 are positioned in the purging conduit 24 and the bypass conduit 34, respectively. The flow restrictors 44, 46 reduce the cross-sectional area of the purging and by-pass conduits, 24, 34 and direct the reactant from the reactant source container 12 to the reaction chamber 14, rather than into the purging and bypass conduits 24, 34 during a reactant pulse.

The dashed line indicates a hot zone 48 within the ALD system 10. Preferably, the temperature within the hot zone 48 is kept at or above the evaporation temperature of the reactant material 18 and preferably below the thermal decomposition temperature of the reactants. Depending upon the reactant, typically the temperature within the hot zone 48 is in the range of about 25 to 500 degrees Celsius. The pressure in the reaction chamber 14 and in the conduits 22, 24, 26, 34 that communicate with the reaction chamber 14 can be atmospheric but more typically the pressure is below atmospheric in the range of about 1 to 100 mbar absolute.

Preferably, the pulsing and purging valves 38, 40 are positioned outside the hot zone 48. That is, within the hot zone 48 there are no valves that can completely close the conduits such that the valves are less subject to thermal degradation. The flow restrictors 44, 46, however, can be positioned within the hot zone 48, as shown. Such an arrangement reduces the chances of condensation within the hot zone 48.

According to the illustrated arrangement, the bypass conduit 34 is not closed by a valve during the pulsing of reactants from the reactant source container 12. As such, during a reactant pulse, a small fraction of the flow of reactant from the reactant source container 12 flows into the bypass conduit 34 and into the evacuation pump 30. As such, the flow restrictor 46 in bypass conduit 34 is preferably sized such that the flow through the bypass conduit 34 is less than about one fifth of that in the reactant conduit 22. More preferably, the flow in the bypass conduit 34 is less than about 15%, and most preferably lest than about 10% of than the flow in the reactant conduit 22.

With continued reference to FIG. 3, the illustrated ALD system preferably also includes a purifier 50 for removing impurities, such as, for example, fine solid particles and liquid droplets originating from the reactant source container 12. The separation of such impurities can be based on the size of the particles or molecules, the chemical character and/or the electrostatic charge of the impurities. In one embodiment, the purifier 50 comprises a filter or a molecular sieve. In other embodiments, the purifier 50 comprises an electrostatic filter or a chemical purifier comprising functional groups capable of reacting with specific chemical compounds present (e.g., water in precursor vapors). Preferably, the purifier 50 is positioned along the reactant conduit 22 between the reactant source container 12 and the reaction chamber 14. More preferably, the purifier 50 is positioned along the reactant conduit 22 at a point between the reactant source container 12 and the connection 56 with the bypass conduit 34. In this manner, the vapor flows in one direction only over the purifier 50, and the gas phase barrier can be formed between the purifier 50 and the reaction chamber 14 during purging.

The ALD system 10 is preferably operated as follows. For a reactant pulse, the pulsing valve 38 is opened while the purging valve 40 is closed. Inactive carrier gas flows through the reactant source container 12 wherein the solid or liquid reactant 18 is vaporized such that a vapor exists in the container 12 above the solid or liquid reactant. Thus, reactant 18 from the reactant source container 12 is carried in vapor form by the carrier gas through the reactant conduit 22, the purifier 50 and the reaction chamber inlet conduit 26 into the reaction chamber 14. There is also a small flow of inactive carrier gas and reactant vapors into bypass conduit 34.

During a purging pulse, the pulsing valve 38 is closed while the purging valve 40 is opened. Purging gas, therefore, flows first through the purging conduit 24 and then through the reaction chamber inlet conduit 26 into the reaction chamber 14. Moreover, a gas phase barrier is formed in a portion 54 of reactant conduit 22 between the junction 56 between the reactant conduit 22 and the by-pass conduit 34 and the inlet conduit 26 of the reaction chamber 14. This purging gas also flows into the bypass conduit 34 and into the evacuation pump 30. As such, the flow direction of gas is reversed for the portion 54 of the reactant conduit 22.

The residual reactant withdrawn via the bypass conduit 34 can be recycled. In such a modified arrangement, the bypass conduit 34 is connected to a condensation vessel maintained at a lower pressure and/or temperature in order to provide condensation of vaporized reactant residues.

The system 10 described above can be extended to include a second reactant source. In such an arrangement, a second reactant source can be positioned within a conduit system in a manner similar to that described above. Such an arrangement is described in U.S. Pat. No. 6,783,590, issued Aug. 31, 2004, which is hereby incorporated by reference herein. Of course the ALD system 10 can also be expanded to more than two reactant sources in light of the disclosure herein.

As mentioned above, one problem associated with ALD systems such as the ALD system 10 described above and other chemical processes that use vaporized liquid and/or solid reactants is that it is difficult to determine how much solid and/or liquid reactant is left in the reactant source container 12. Accordingly, as described above, the illustrated system includes the monitoring apparatus 100 for determining the partial pressure of the gas phase reactant in the reactant conduit 22 and/or determining the amount or reactant consumed within the reactant source container 12.

In addition or in the alternative, the monitoring apparatus 100 may also be configured to detect if the reactant 18 in the container 12 has been contaminated. For example, with respect to a metal halide reactant, crystalline water in solid metal halides may render most of the metal halide non-volatile. Specifically, when moist metal halide is heated, the water reacts with the metal halide already at temperatures below the sublimation temperature of the metal halide and releases a hydrogen halide (e.g. HCl) vapor. This may leave non-volatile metal oxyhalide in the reactant container. It would be useful to provide a method and apparatus for testing if a new metal halide reactant source container has been contaminated with water before using the container for thin film deposition.

The signal from the partial pressure sensor 102 may be used to determine if the container has been contaminated. For example, an HfCl₄ solid source is usually operated in a carrier gas mode in which an inactive gas, for example N₂, is pulsed into the solid reactant source container 12. The N₂ gas carries any released vapor from the solid reactant source container 12 into the reaction space of the ALD reactor 14. Because HCl vapor has about 45% lower thermal conductivity than N₂ gas, the signal from the second pressure sensor 110 is significantly affected by the presence of HCl vapor. Accordingly, a significant deviation in the measured partial pressure from the expected partial pressure would indicate contamination of the container 12. In this manner, the partial pressure sensor 102 reveals whether or not a new container 12 of HfCl₄ is dry enough, for example, for the deposition of hafnium dioxide HfO₂ thin films. In a similar manner, the partial pressure sensor 102 may be used to detect the contamination of other reactants.

It should be noted that certain objects and advantages of the invention have been described above for the purpose of describing the invention and the advantages achieved over the prior art. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Moreover, although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. For example, it is contemplated that various combinations or subcombinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above, but should be determined only by a fair reading of the claims that follow.

We claim:

1. A partial pressure sensor apparatus for determining the partial pressure of a first component in a gas stream having a composition comprising at least the first component and one other component; comprising:
a first pressure sensor that has a first sensitivity to the composition of the gas stream;
a second pressure sensor that has a second sensitivity to the composition of the gas stream, the second sensitivity being greater than the first sensitivity;
a control unit that is configured to compare a first pressure signal from the first pressure sensor to a second pressure signal from the second pressure sensor to determine the partial pressure of the first component in the gas stream.

2. The partial pressure sensor apparatus as in claim 1, wherein the first pressure sensor is substantially insensitive to the composition of the gas stream.

3. The partial pressure sensor apparatus as in claim 2, wherein the first pressure sensor comprises a mechanical pressure sensor.

4. The partial pressure sensor apparatus as in claim 3, wherein the mechanical pressure sensor comprises a piezoelectric pressure sensor.

5. The partial pressure sensor apparatus as in claim 3, wherein the mechanical pressure sensor comprises a capacitive pressure sensor.

6. The partial pressure sensor apparatus as in claim 2, wherein the second pressure sensor comprises a Pirani pressure sensor.

7. The partial pressure sensor apparatus as in claim 1, wherein the control unit is configured to calculate the difference between the first signal from the first pressure sensor and the second signal from the second pressure sensor, the difference between the first signal and the second signal being proportional to the partial pressure of the first component in the gas stream.

8. A method for determining the partial pressure of a first component in a gas stream having a composition comprising at least the first component and one other component; the method comprising:
measuring the pressure of the gas stream using a first pressure sensor that has a first sensitivity to the composition of the gas stream;
measuring the pressure of the gas stream using a second pressure sensor that has a second sensitivity to the composition of the reactant stream, the second sensitivity being greater than the first sensitivity; and
comparing a first pressure signal from the first pressure sensor to a second pressure signal from the second pressure sensor to determine the partial pressure of the first component in the gas stream.

9. The method as in claim 8, wherein comparing the first pressure signal from the first pressure sensor to the second pressure signal from the second pressure sensor to determine the partial pressure of the first component of the gas stream comprises determining the difference between the signal of the first pressure sensor and the signal of the second pressure sensor.

10. The method as in claim 9, further comprising generating an alarm signal when the difference between the signal of the first pressure sensor and the signal of the second pressure sensor exceeds a predetermined level.

11. The method as in claim 9, further comprising integrating over time the difference between the signal of the first pressure sensor and the signal of the second pressure sensor to determine a first value.

12. The method as in claim 11, further comprising comparing the first value to a reference valued determined by integrating over time the difference between a signal of a first pressure sensor and a signal of a second pressure sensor for a reference source container.

13. The method as in claim 9, wherein the first component comprises reactant vapor generated from a solid or liquid reactant source.

14. A method for determining the changes in a reactant supply system that is design to supply repeated pulses of a vapor phase reactant to a reaction chamber of an ALD system, the method comprising:
providing a purging gas source;
providing a reactant source that comprises a solid or liquid reactant and a vaporizing mechanism for producing a first vapor phase reactant;
providing a conduit system to connect the reactant source to the reaction chamber and to connect the purging gas source to the reaction chamber;
providing at least one valve positioned in the conduit system such that switching of the valve induces alternating vapor phase reactant pulses from the reactant source to the reaction chamber and purging pulses from the purging gas source to the reaction chamber;
repeatedly switching the valve to induce repeated alternating vapor phase reactant and purging pulses;
measuring the pressure in the conduit system with a first pressure sensor that has a first sensitivity to the composition of the gas stream;
measuring the pressure in the conduit system with a second pressure sensor that has a second sensitivity to the composition of the reactant stream, the second sensitivity being greater than the first sensitivity; and
comparing the first signal to the second signal.

15. The method as in claim 14, further comprising determining the partial pressure of the first reactant in the conduit system.

16. The method as in claim 14, wherein the step of comparing the first signal to the second signal comprises determining the difference between the signal of the first pressure sensor and the signal of the second pressure sensor.

17. The method as in claim 16, further comprising generating an alarm signal when the difference between the signal of the first pressure sensor and the signal of the second pressure sensor exceeds a predetermined level.

18. The method as in claim 16, further comprising integrating over time the difference between the signal of the first pressure sensor and the signal of the second pressure sensor to determine a first value.

19. The method as in claim 18, further comprising comparing the first value to a reference valued determined by integrating over time a difference between a signal of a first pressure sensor and a signal of a second pressure sensor in a reference container.

20. An apparatus for supplying repeated vapor phase reactant pulses to a reaction chamber, the apparatus comprising:
a reactant source for a first reactant;
a gas conduit system that connects the reactant source and the reaction chamber;
a valve positioned in the gas conduit system such that switching of the valve induces vapor phase reactant pulses from the reactant source to the reaction chamber;
a first pressure sensor that has a first sensitivity to the composition of the gas stream;
a second pressure sensor that has a second sensitivity to the composition of the reactant stream, the second sensitivity being greater than the first sensitivity; and
a control unit that is configured to compare a first pressure signal from the first pressure sensor to a second pressure sensor from the second pressure signal.

21. The apparatus as in claim 20, wherein the control unit is configured to determine a partial pressure of the first reactant in the gas conduit system.

22. A semiconductor processing tool, comprising:
a reactant source comprising a solid or liquid phase reactant;
a reactor;
a conduit system for placing the reactant source in communication with the reactor;
a first pressure sensor for measuring the pressure in the conduit system;
a second pressure sensor for measuring the pressure in the conduit system; and
a monitoring apparatus configured to compare the measurements of the first pressure sensor and the second pressure sensor and relate the comparison to an amount of solid or liquid phase reactant left in the reactant source.
